(19) United States
(12) Patent Application Publication
(10) Pub. No.: US 2005/0014330 A1
(43) Pub. Date: Jan. 20, 2005

(54) Method of planarizing an interlayer dielectric layer

(75) Inventors: Young-Rae Park, (US); Jae-Dong Lee, (US); Joon Sang Park, (US); Chang-Ki Hong, (US)

Correspondence Address: F. CHAU & ASSOCIATES, LLC, 130 WOODBURY ROAD, WOODBURY, NY, 11797, US

(73) Assignee: SAMSUNG ELECTRONICS CO., LTD.

(21) Appl. No.: 10/777,864

(22) Filed: Feb. 12, 2004

(30) Foreign Application Priority Data
Jul. 15, 2003 (KR) 2003-48432

(51) Int. Cl. H01L 21/8242; H01L 21/4763

(52) U.S. Cl. 438/239; 438/634

(57) ABSTRACT

A method of planarizing an interlayer dielectric layer formed over a one cylinder storage (OCS) capacitor including applying two or three interlayer dielectric layers over the capacitor and planarizing the interlayer dielectric layers using CMP having a different etching selectivity according to the layers.

### BACKGROUND OF THE INVENTION

This application claims priority based on Korean Patent Application No. 2003-48432, filed on Jul. 15, 2003.

1. Technical Field

The present invention relates to a method of manufacturing a semiconductor device, and more particularly, to a method of planarizing an interlayer dielectric layer formed over a one cylinder storage (OCS) capacitor.

2. Discussion of Related Art

Semiconductor devices, such as dynamic random access memories (DRAMs), need to ensure a sufficient cell capacitance in a limited area. In general, sufficient cell capacitance is achieved by using a high dielectric layer, reducing the thickness of the dielectric layer, or increasing an effective area of a lower electrode. Increasing the effective area of the lower electrode is the most favorable approach because it can be implemented using a relatively simple process and dielectric layers do not need to be modified.

A conventional method of increasing the effective area of a lower electrode includes using a one-cylinder storage (OCS) capacitor in which a lower electrode is formed in the shape of a cylinder to increase the height of the lower electrode. A disadvantage of this method is that as the height of the lower electrode increases, a difference in height between a cell region where the capacitor is formed and a peripheral circuit region where the capacitor is not formed increases.

For example, FIG. 1 is a cross-sectional view illustrating a state in which a conventional OCS capacitor 70 is formed on a semiconductor substrate 10. Referring to FIG. 1, contact pads 30 each of which is self-aligned by two adjacent gates 20 are formed in a cell region C. A contact plug 45 is formed on the contact pad 30. Reference numerals 25 and 35 denote insulating layers. A cylinder-shaped lower electrode 55a is formed on the contact plug 45. A dielectric layer 60 and an upper electrode 65 are sequentially formed on the lower electrode 55a to form the capacitor 70. The dielectric layer 60 and the upper electrode 65 are patterned and removed in a peripheral circuit region P. As shown in FIG. 1, there is a difference in height between the cell region C and the peripheral circuit region P that is as high as the capacitor 70.

An interlayer dielectric layer should be formed over the capacitor 70 to ensure insulation between the capacitor 70 and metal lines formed in a subsequent process. The interlayer dielectric layer must be planarized to reduce any further difference between the heights of the cell region and the peripheral region.

Many problems may occur if a proper planarization process is not carried out. For example, when contact holes are formed for connection to metal lines by depositing a tungsten layer, the tungsten layer existing on inclined areas is not easily removed during a subsequent plasma etch back process to form a tungsten plug, resulting in a leakage current after formation of the metal lines.

Also, as semiconductor devices become more highly integrated, a chemical mechanical polishing (CMP) technology is preferred over the etch back technology using plasma to remove the tungsten layer existing on areas other than the contact holes. It is impossible to employ the CMP technology if there exists the above-described height difference.

Further, a wide difference between the cell region and the peripheral circuit region lowers a process margin for a depth of focus (DOF) in patterning a photosensitive layer for the metal lines. Accordingly, it is difficult to pattern the photosensitive layer and to form highly integrated metal lines.

A conventional method of planarizing an interlayer dielectric layer is described with reference to FIGS. 2 through 5.

Referring to FIG. 2, an interlayer dielectric layer 75 is formed over the peripheral circuit region P and the cell region C as shown in FIG. 1. The interlayer dielectric layer 75 formed in the peripheral circuit region P needs to be higher than the capacitor 70 formed in the cell region C. Next, a photosensitive layer, such as a photoresist, is applied over the interlayer dielectric layer 75 and a photosensitive layer pattern 80 is formed through a photolithography process so that the cell region C is exposed.

Referring to FIG. 3, the interlayer dielectric layer 75 in the exposed cell region C is etched by a predetermined depth to form an etched interlayer dielectric layer 75a. The etched interlayer dielectric layer 75a has substantially the same height across the cell region C and the peripheral circuit region P.

The photosensitive layer pattern 80 is removed and cleaned such that a protrusion portion 77 is formed between the cell region C and the peripheral circuit region P as shown in FIG. 4. The protrusion portion 77 is removed using a CMP process. After the CMP process, the etched interlayer dielectric layer 75a is planarized to form a planarized interlayer dielectric layer 75b as shown in FIG. 5. Metal deposition is performed on the planarized interlayer dielectric layer 75b, and metal lines 90 are formed by a photolithography process.

The protrusion portion 77 may remain on the planarized interlayer dielectric layer 75b even after the CMP process. If a CMP process is overly performed when removing the remaining protrusion portion 77, the planarized interlayer dielectric layer 75b in the cell region C may be excessively etched, thereby damaging the upper electrode 65 of the capacitor 70 and adversely affecting the semiconductor device.

Furthermore, the conventional method employs a photolithography process as described with reference to FIGS. 2 and 3, and a CMP process to remove the protrusion portion 77 as described with reference to FIG. 4. Consequently, the process throughput is reduced.

DRAM devices require reliable and cost-effective chips. One of the most expensive processes in manufacturing DRAM devices is the photolithography process. Expensive consumables such as photosensitive layers and reticles are required to perform the photolithography process, and a subsequent cleaning process after an etching process should be performed. As a result, manufacturing costs are high using the conventional planarization method.

### SUMMARY OF THE INVENTION

A method of planarizing an interlayer dielectric layer according to an embodiment of the invention includes forming a first interlayer dielectric layer over a first region in which a capacitor is formed and a second region adjacent to the first region, the first region being higher than the second region. A second interlayer dielectric layer is formed over the first interlayer dielectric layer. The second interlayer dielectric layer has an etching selectivity different from that of the first interlayer dielectric layer. A third interlayer dielectric layer is formed over the second interlayer dielectric layer. The third interlayer dielectric layer has an etching selectivity different from that of the second interlayer dielectric layer. The third and second interlayer dielectric layers are chemical mechanical polished in the first region using the third interlayer dielectric layer in the second region and the first interlayer dielectric layer in the first region as etching end points.

The third interlayer dielectric layer may have the same etching selectivity as that of the first interlayer dielectric layer. The second interlayer dielectric layer may have a lower etching rate in the chemical mechanical polishing step than that of the first and third interlayer dielectric layers. The third interlayer dielectric layer may be formed so that the third interlayer dielectric layer in the second region is higher than the first interlayer dielectric layer in the first region.

The first interlayer dielectric layer may be made of a material selected from a group consisting of flow fill, SiLK, SiOC, black diamond, CORAL, undoped polysilicon, SiN, SiON, BN, anti reflection coating (ARC), and a combination of these materials. The first interlayer dielectric layer may be formed by first applying a material selected from the group consisting of boro-phosphorus silicate glass (BPSG), phosphorus silicate glass (PSG), plasma enhanced tetraethylorthosilicate (PETEOS), high density plasma oxide, and a combination of these materials and then applying a material selected from the group consisting of flow fill, SiLK, SiOC, black diamond, CORAL, undoped polysilicon, SiN, SiON, BN, ARC, and a combination of these materials. The second interlayer dielectric layer may be made of a material selected from a group consisting of plasma enhanced oxide (PEOX), undoped silicate glass (USG), spin on glass (SOG), flowable oxide (FOX), BPSG, PSG, PETEOS, and a combination of these materials. Further, the third interlayer dielectric layer may be made of the same material as that of the first interlayer dielectric layer.

The third and second interlayer dielectric layers may be chemical mechanical polished using a slurry having an etching selectivity between the second and third interlayer dielectric layers that is greater than 5:1, and the slurry may be a ceria slurry when the third and second interlayer dielectric layers are made of a material selected from the previously mentioned group. More preferably, the third and second interlayer dielectric layers may be chemical mechanical polished by removing the third interlayer dielectric layer in the first region using a first slurry that etches the third interlayer dielectric layer at a higher etch rate than that of the second interlayer dielectric layer or a first slurry that has the same etching selectivity between the second and third interlayer dielectric layers, and removing the second interlayer dielectric layer in the first region using a second slurry etches the second interlayer dielectric layer at a higher etch rate than that of the first and third interlayer dielectric layers. The second slurry may have an etching selectivity between the second interlayer dielectric layer and the third interlayer dielectric layer that is greater than 5:1. When a material selected from the previously mentioned group is used, the second slurry may be a ceria slurry. The first slurry that etches the third interlayer dielectric layer at a higher etch rate than that of the second interlayer dielectric layer may be a silica slurry. The third and second interlayer dielectric layers may also be chemical mechanical polished using a mangania slurry, an alumina slurry, or a combination of a mangania slurry, an alumina slurry, a silica slurry and a ceria slurry.

The materials of the first through third interlayer dielectric layers may be deposited in reverse order. For example, the first and third interlayer dielectric layers may be made of a material selected from a group consisting of PEOX, USG, SOG, FOX, BPSG, PSG, PETEOS, and a combination of these materials, and the second interlayer dielectric layer may be made of a material selected from a group consisting of flow fill, SiLK, SiOC, black diamond, CORAL, undoped polysilicon, SiN, SiON, BN, ARC, and a combination of these materials.

A method of planarizing an interlayer dielectric layer according to another embodiment of the invention includes depositing two interlayer dielectric layers and chemical mechanical polishing the interlayer dielectric layers. A first interlayer dielectric layer is formed over a first region in which a capacitor is formed and a second region adjacent to the first region, the first region being higher than the second region. A second interlayer dielectric layer is formed over the first interlayer dielectric layer. The second interlayer dielectric layer has an etching selectivity different from that of the first interlayer dielectric layer. The second interlayer dielectric layer is chemical mechanical polished in the first region using a slurry that etches the second interlayer dielectric layer at a higher etch rate than that of the first interlayer dielectric layer and using the first interlayer dielectric layer in the first region as an etching end point.

The first interlayer dielectric layer may be made of a material selected from a group consisting of PEOX, USG, FOX, BPSG, PSG, PETEOS, and a combination of these materials, and the second interlayer dielectric layer may be made of a material selected from a group consisting of flow fill, SiLK, SiOC, black diamond, CORAL, undoped polysilicon, SiN, SiON, BN, ARC, and a combination of these materials.

### BRIEF DESCRIPTION OF THE DRAWINGS

The present invention will become more apparent by describing in detail exemplary embodiments thereof with reference to the attached drawings in which:

FIG. 1 is a cross-sectional view showing a one-cylinder storage (OCS) capacitor formed on a semiconductor substrate;

FIGS. 2 through 5 are cross-sectional views illustrating a conventional method of planarizing an interlayer dielectric layer formed over a capacitor;

FIGS. 6 through 9 are cross-sectional views illustrating steps in a method of planarizing an interlayer dielectric layer according to a an embodiment of the present invention;

FIGS. 10 and 11 are graphs illustrating removal rate and selectivity of a silica slurry and a ceria slurry, respectively; and

FIGS. 12 and 13 are cross-sectional views illustrating steps in a method of planarizing an interlayer dielectric layer according to another embodiment of the present invention.

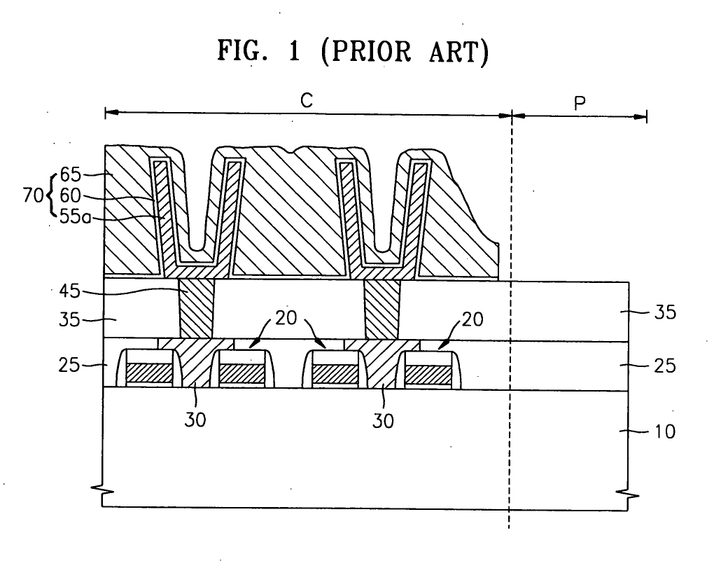

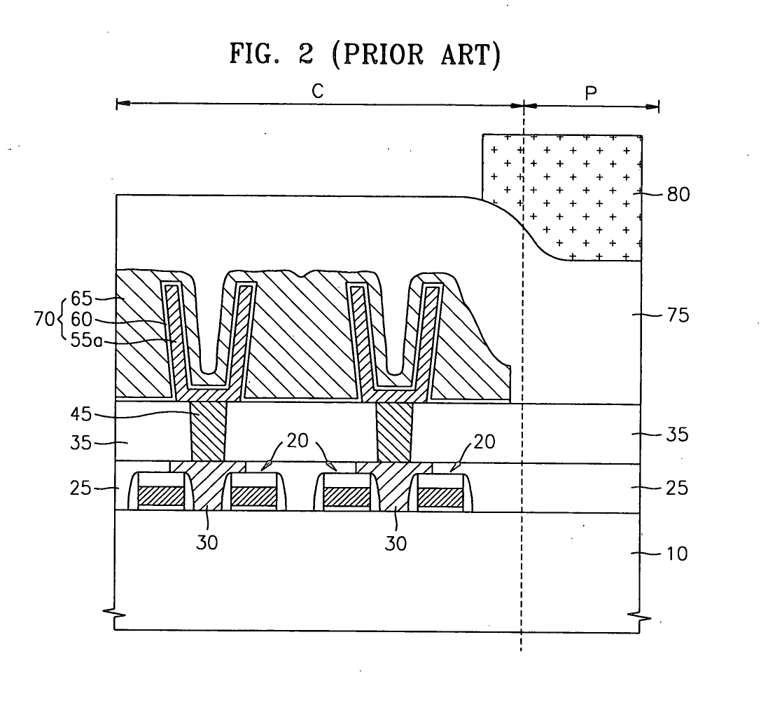

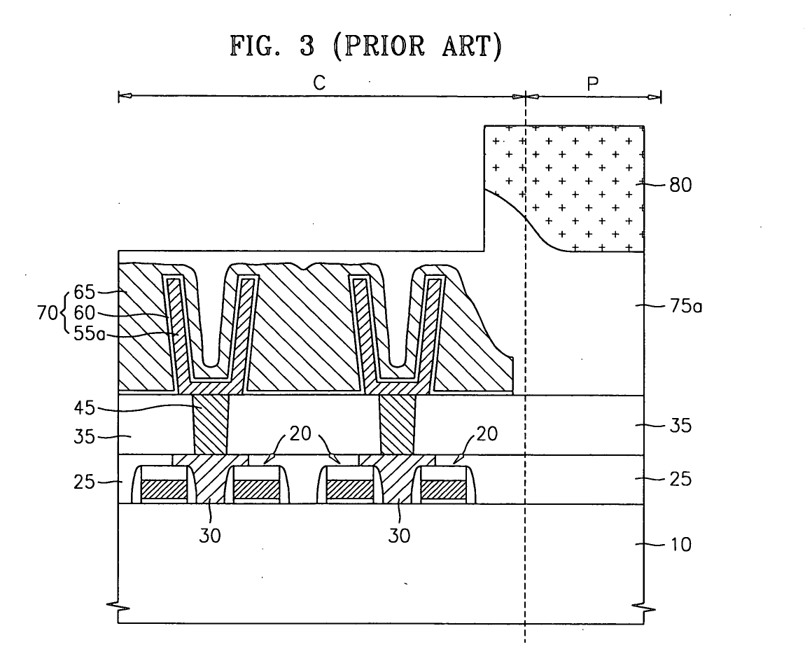

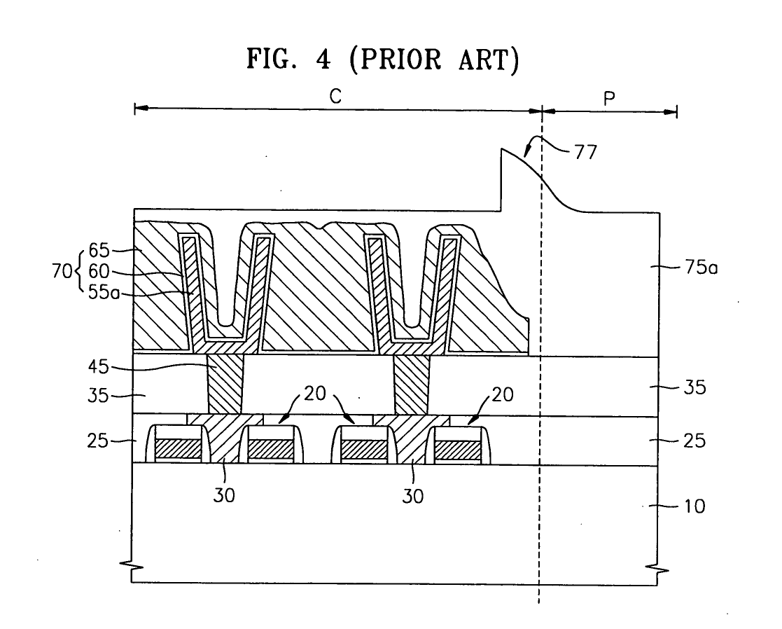

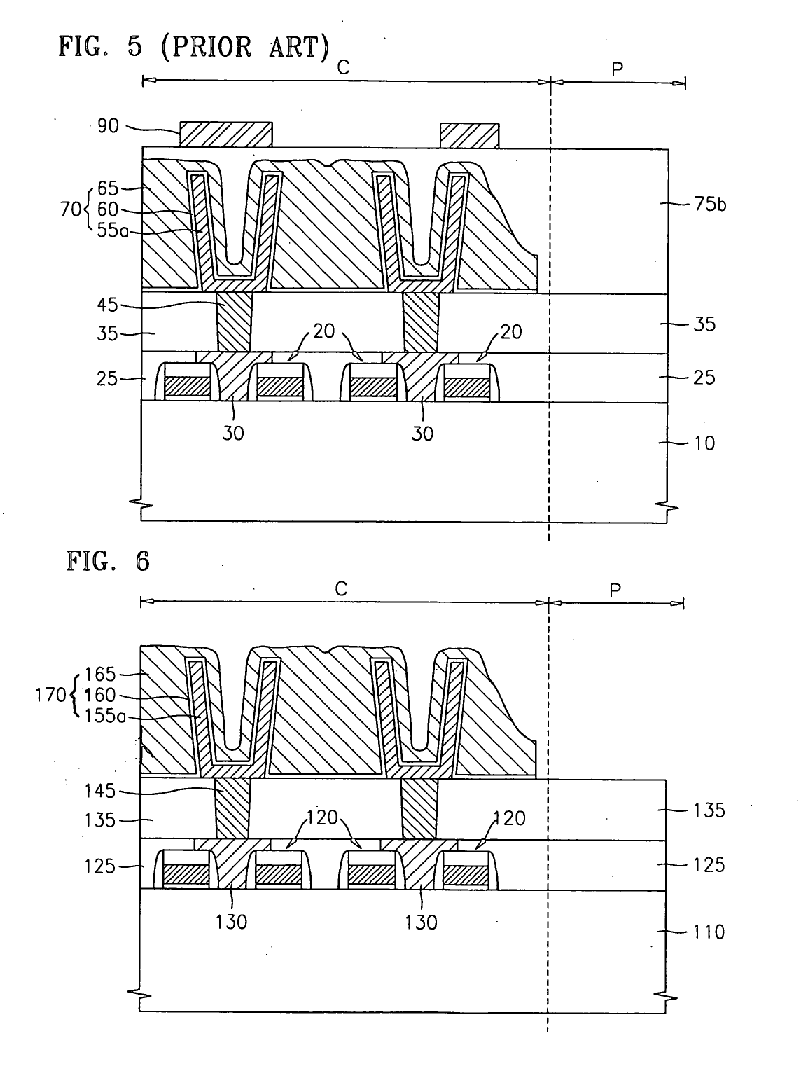

### DETAILED DESCRIPTION OF PREFERRED EMBODIMENTS

The present invention will now be described more fully with reference to the accompanying drawings, in which preferred embodiments of the invention are shown. To facilitate understanding, identical reference numerals have been used, where possible, to designate identical elements that are common to the figures.

FIGS. 6 through 9 are cross-sectional views illustrating steps in a method of planarizing an interlayer dielectric layer according to an embodiment of the present invention.

FIG. 6 is a cross-sectional view showing a one-cylinder storage (OCS) capacitor 170 formed on a semiconductor substrate 110. Referring to FIG. 6, a cell region C and a peripheral circuit region P are defined in the semiconductor substrate 110. Contact pads 130 each of which is self-aligned by two adjacent gates 120 are formed in the cell region C. A contact plug 145 is formed on a top surface of the contact pad 130. Reference numerals 125 and 135 denote insulating layers.

A cylinder-shaped lower electrode 155a is formed on the contact plug 145. The capacitor 170 is formed in the cell region C by sequentially forming a dielectric layer 160 and an upper electrode 165 on the lower electrode 155a. The dielectric layer 160 and the upper electrode 165 formed in the peripheral circuit region P are patterned and removed. As shown in FIG. 6, there is a difference in height between the cell region C and the peripheral circuit region P that is as high as the capacitor 170. In a highly integrated dynamic random access memory (DRAM), the height of the capacitor 170 is approximately 15,000 Å.

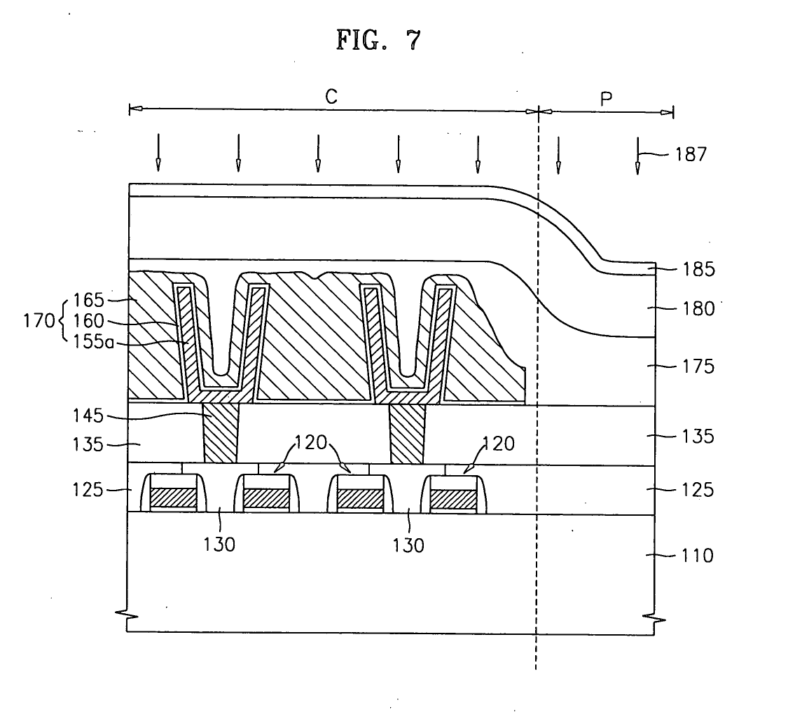

To perform a subsequent metal depositing process, as shown in FIG. 7, a first interlayer dielectric layer 175 is formed over both the cell region C and the peripheral circuit region P to provide insulation between the capacitor 170 and metal lines.

The first interlayer dielectric layer 175 can act as an etching end point which stops further etching in the cell region C during a subsequent chemical mechanical polishing (CMP) process. The first interlayer dielectric layer 175 preferably has a thickness of about 1,000 Å to about 4,000 Å. The first interlayer dielectric layer 175 is made of a material selected from a group consisting of flow fill, SiLK, SiOC, black diamond, tetramethylcyclotetrasilane (known as CORAL), undoped polysilicon, SiN, SiON, BN, anti reflection coating (ARC) and a combination of these materials. Alternatively, the first interlayer dielectric layer 175 is formed by first applying a material selected from a group consisting of boro-phosphorus silicate glass (BPSG), phosphorus silicate glass (PSG), plasma enhanced tetraethylorthosilicate (PETEOS), high density plasma oxide, and a combination of these materials and then applying a material selected from a group consisting of flow fill, SiLK, SiOC, black diamond, CORAL, and a combination of these materials. BPSG and PSG are deposited by chemical vapor deposition (CVD), as is well known in the art. SiN, SiON, PETEOS and HDP are deposited by plasma enhanced chemical vapor deposition (PE-CVD). Black diamond is formed by PE-CVD using a reaction between trimethylsilane and oxygen.

A second interlayer dielectric layer 180 is formed on the first interlayer dielectric layer 175. The second interlayer dielectric layer 180 has an etching selectivity different from that of the first interlayer dielectric layer 175, and serves as a sacrificial layer for planarization during a selective CMP process. The second interlayer dielectric layer 180 is preferably made of a material selected from a group consisting of plasma enhanced oxide (PEOX), undoped silicate glass (USG), spin on glass (SOG), flowable oxide (FOX), BPSG, PSG, PETEOS, and a combination of these materials. EPOX is deposited by PE-CVD. USG, PSG, and BPSG are deposited by CVD. SOG and FOX are formed by a spin coating process. The second interlayer dielectric layer 180 preferably has a thickness of about 20,000 Å.

A third interlayer dielectric layer 185 having properties different from those of the second interlayer dielectric layer 180 is formed on the second interlayer dielectric layer 180. The third interlayer dielectric layer 185 has characteristics similar or equal to those of the first interlayer dielectric layer 175, and has an etching selectivity different from that of the second interlayer dielectric layer 180. The third interlayer dielectric layer 185 serves as an etch stop layer during a CMP process. The third interlayer dielectric layer 185 may have the same etching selectivity as that of the first interlayer dielectric layer 175. Further, the third interlayer dielectric layer may be made of the same material as that of the first interlayer dielectric layer 175. Accordingly, as previously described, the third interlayer dielectric layer 185 may be made of a material selected from a group consisting of flow fill, SiLK, SiOC, black diamond, CORAL, undoped polysilicon, SiN, SiON, BN, ARC, and a combination of these materials. The second interlayer dielectric layer 180 is preferably made of a material having a lower etching rate in the subsequent CMP process than that of the first and third interlayer dielectric layers 175 and 185. The third interlayer dielectric layer 185 in the lower peripheral circuit region P is higher than the first interlayer dielectric layer 175 in the higher cell region C. The third interlayer dielectric layer 185 may have a thickness of approximately 1,500 Å.

A first CMP process 187 is performed on condition that the third interlayer dielectric layer 185 is more easily removed than the second interlayer dielectric layer 180. For example, a slurry that etches the third interlayer dielectric layer 185 at a higher etching rate than that of the second interlayer dielectric layer 180 is used. When the material is selected from the previously mentioned group, a silica slurry can be used. At an initial phase of the process of planarizing the third interlayer dielectric layer 185, the third interlayer dielectric layer 185 in the cell region C is removed, but the third interlayer dielectric layer 185 in peripheral circuit region P is only slightly removed. When the third interlayer dielectric layer 185 in the cell region C is completely removed and the second interlayer dielectric layer 180 is initially exposed, an etching rate is reduced drastically. As a result, since the degree of removal of the second interlayer dielectric layer 180 in the cell region C is sharply reduced, the lower electrode 155a is not attacked due to over-etching during a CMP process.

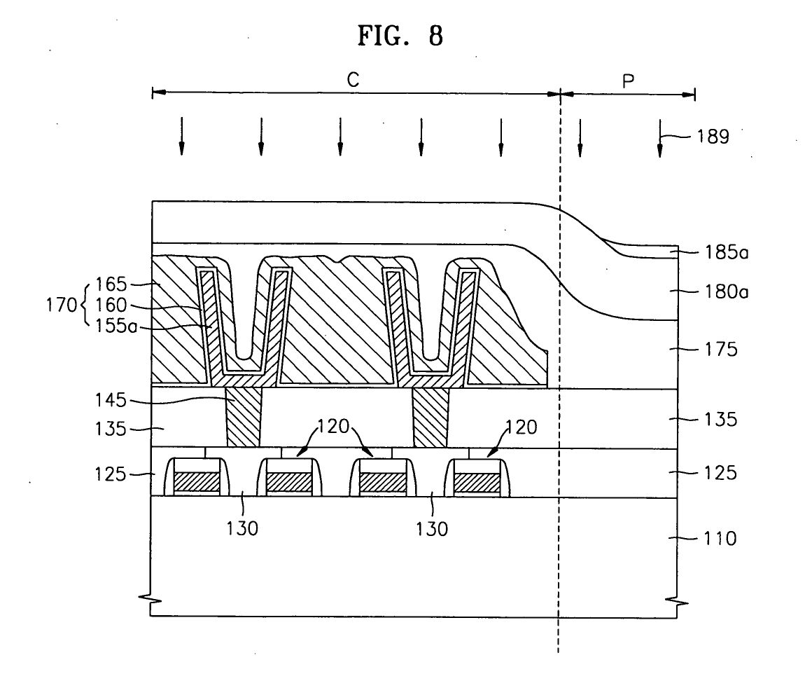

The resultant structure after the first CMP process 187 is illustrated in FIG. 8. A third interlayer dielectric layer 185a remains in the peripheral circuit region P and is used as an etch stop layer in a subsequent process. A second interlayer dielectric layer 180a remains after a portion of the second interlayer dielectric layer 180 in the cell region C is slightly removed. A second CMP process 189 is performed on the second interlayer dielectric layer 180a in cell region C under the condition that the second interlayer dielectric layer 180a is more easily removed than the third interlayer dielectric layer 185a. For example, a slurry that etches the second interlayer dielectric layer 180a at a higher etching rate than that of the first and third interlayer dielectric layers 175 and 185a is used. The second CMP process 189 eliminates the difference in height between the cell region C and the peripheral circuit region P. The slurry preferably has an etching selectivity between the second interlayer dielectric layer 180a and the third interlayer dielectric layer 185a that is greater than 5:1. When a material selected from the previously mentioned group is used, a ceria slurry is preferably used.

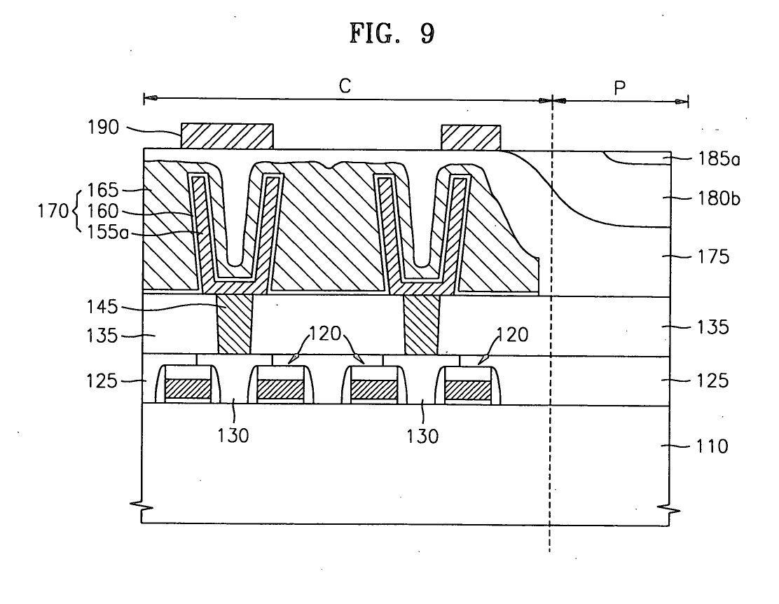

Since the second CMP process is performed on condition that the second interlayer dielectric layer 180a is more easily etched, the second interlayer dielectric layer 180a can be planarized by using the third interlayer dielectric layer 185a in the peripheral circuit region P and the first interlayer dielectric layer 175 in the cell region C as etching end points. As illustrated in FIG. 9, the resultant structure includes a second interlayer dielectric layer 180b remaining in the peripheral circuit region P. Metal lines 190 are formed in subsequent metal depositing and photolithography processes.

As described above, the chemical mechanical polishing of the third and second interlayer dielectric layers 185 and 180 preferably includes removing the third interlayer dielectric layer 185 in the cell region region C using a slurry that etches the third interlayer dielectric layer 185 at a higher etch rate than that of the second interlayer dielectric layer 180, and removing the second interlayer dielectric layer 180a in the cell region C using a slurry that etches the second interlayer dielectric layer 180a at a higher etch rate than that of the first and third interlayer dielectric layers 175 and 185a. However, in other embodiments of the invention, the first planarization can be performed using a slurry that has the same etching selectivity between the second and third interlayer dielectric layers 180 and 185 and the second planarization can be performed using a slurry that has a selectivity greater than 5:1.

In other embodiments of the invention, the first CMP process using silica slurry is not used, and a single CMP process using a ceria slurry having an etching selectivity between the second interlayer dielectric layer 180 and the third interlayer dielectric layer 185 that is greater than 5:1 can be performed for planarization as shown in FIG. 9. The slurry used in chemical mechanical polishing of the third and second interlayer dielectric layers 185 and 180 is not limited to those noted above but can be a mangania slurry, an alumina slurry, or a combination of mangania slurry, alumina slurry, silica slurry and ceria slurry.

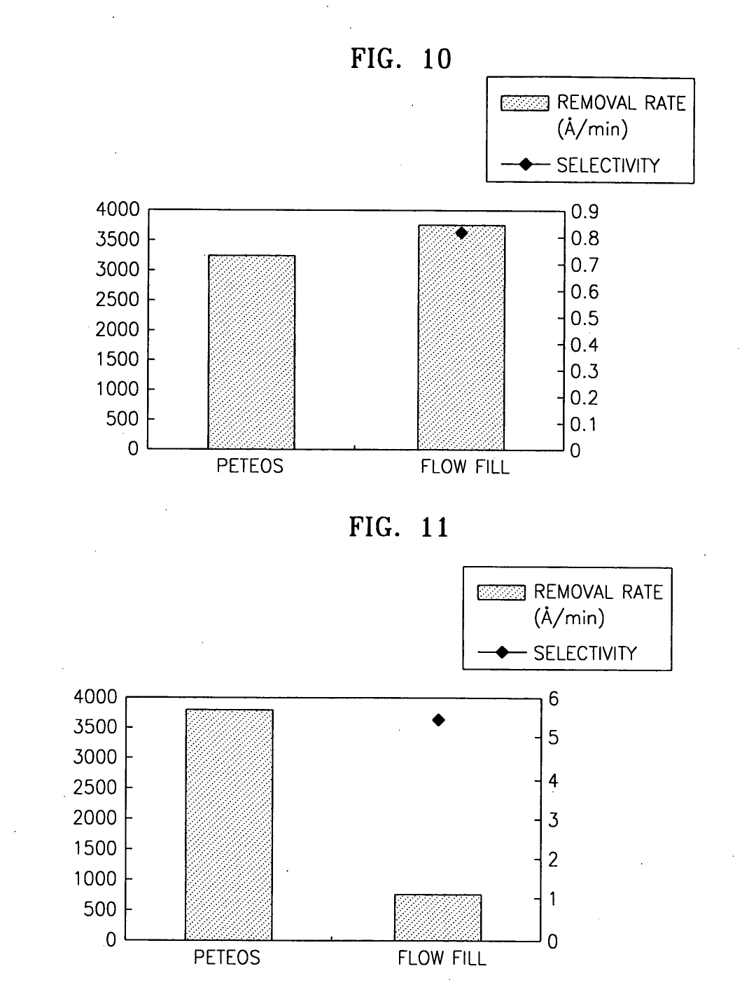

FIGS. 10 and 11 are graphs illustrating removal rate and selectivity of a silica slurry and a ceria slurry, respectively. As shown in FIG. 10, the removal rate (etching rate) of flow fill, which was used to form the first and/or third interlayer dielectric layer(s), is greater than PETEOS, which was used to form the second interlayer dielectric layer. As shown in FIG. 11, selectively between PETEOS and flow fill is about 5.4:1. The graphs of FIGS. 10 and 11 show that a CMP process that selectivity removes the second interlayer dielectric layer can be effectively performed using ceria slurry.

In the above-described exemplary embodiments of the present invention, three interlayer dielectric layers are formed, the second interlayer dielectric layer is an etch stop layer in a first CMP process, and the first and third interlayer dielectric layers are etch stop layers in a second CMP process. Thus, an expensive photolithography process is not required, thereby reducing production cost and improving process throughput.

In other exemplary embodiments of the invention, the materials of the first through third interlayer dielectric layers may be deposited in reverse order. For example, the first and third interlayer dielectric layers can be made of a material selected from a group consisting of PEOX, USG, SOG, FOX, BPSG, PSG, PETEOS, and a combination of these materials, and the second interlayer dielectric layer can be made of a material selected from a group consisting of flow fill SiLK, SiOC, black diamond, CORAL, undoped polysilicon, SiN, SiON, BN, ARC, and a combination of these materials.

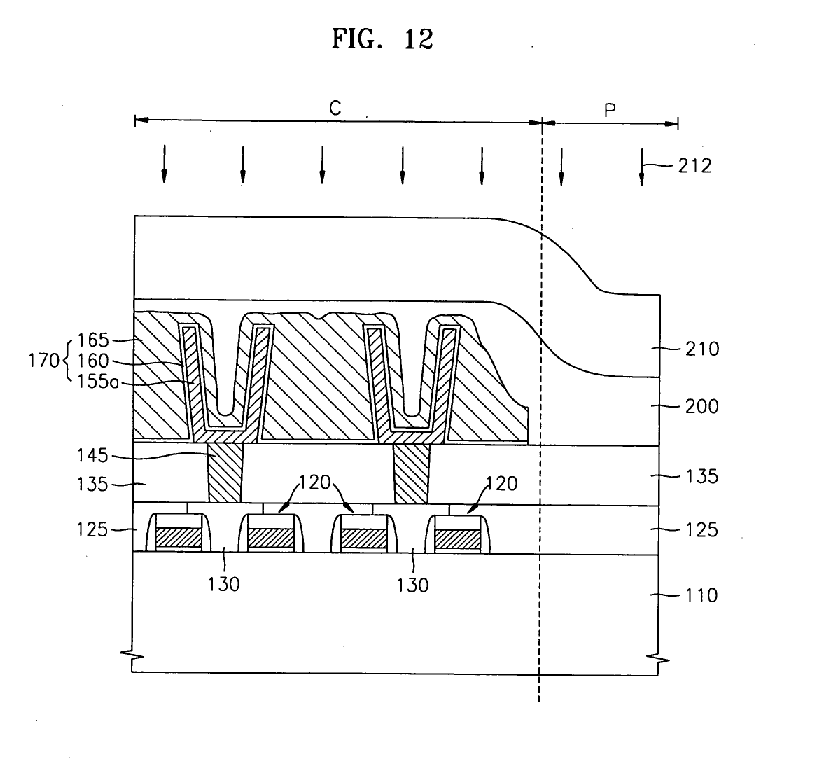

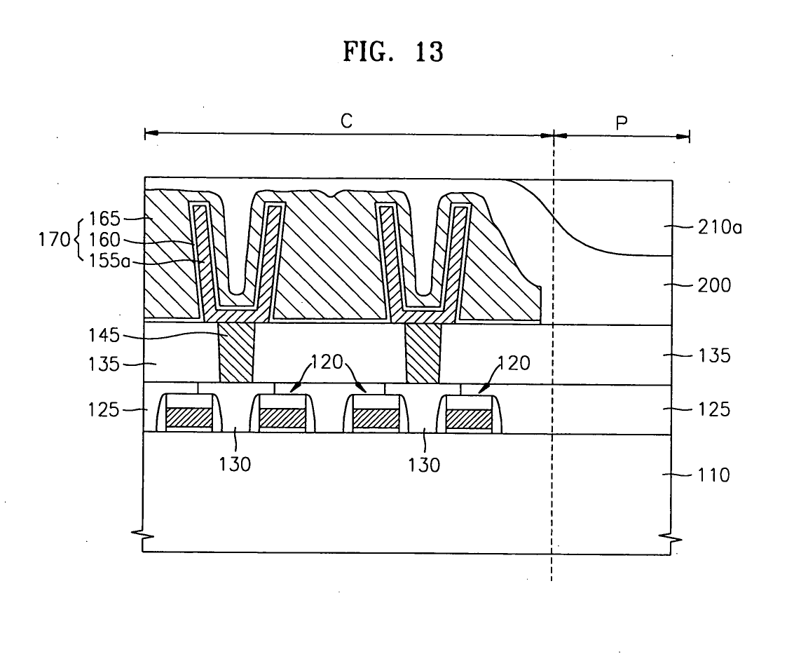

FIGS. 12 and 13 are cross-sectional views illustrating steps in a method of planarizing an interlayer dielectric layer according to another preferred embodiment of the present invention.

In this preferred embodiment of the invention, two interlayer dielectric layers are deposited and then are subjected to a chemical mechanical polishing process. As shown in FIG. 12, a first interlayer dielectric layer 200 is formed both over a cell region C and a lower peripheral circuit region P. A second interlayer dielectric layer 210 is formed on the first interlayer dielectric layer 200. The second interlayer dielectric layer 210 functions as a sacrificial layer having a different etching selectivity from that of the first interlayer dielectric layer 200. The second interlayer dielectric layer 210 in the peripheral circuit region P is higher than the first interlayer dielectric layer 200 in the cell region C. The first interlayer dielectric layer 200 is made of a material selected from a group consisting of PEOX, USG, FOX, BPSG, PSG, PETEOS, and a combination of these materials, and the second interlayer dielectric layer 210 is made of a material selected from a group consisting of flow fill, SiLK, SiOC, black diamond, CORAL, undoped polysilicon, SiN, SiON, BN, ARC, and a combination of these materials. Accordingly, the first interlayer dielectric layer has an etching selectivity that is different from that of the second interlayer dielectric layer when a predetermined slurry is used.

The second interlayer dielectric layer 210 in cell region C is subjected to a chemical mechanical polishing process using a slurry, such as a silica slurry, that etches the second interlayer dielectric layer 210 at a higher etch rate than that of the first interlayer dielectric layer 200. The first interlayer dielectric layer 200 in the cell region acts as an etching end point. Consequently, the first interlayer dielectric layer 200 and the second interlayer dielectric layer 210 are planarized as shown in FIG. 13.

According to the present embodiment of the invention, a double-interlayer dielectric layer structure is formed, instead of the triple-interlayer dielectric layer structure of previously described embodiments, and thus a simpler process can be achieved.

As described above, because the photolithography process performed to expose the cell region in the conventional planarization method is omitted, a simple process can be achieved, process throughput can be enhanced, and manufacturing costs can be considerably reduced. Furthermore, because a selective CMP process is carried out, in-wafer spread can be improved. Because the number of process steps is reduced, the possibility of defects occurring during manufacturing is also reduced, resulting in stable operation of a resulting semiconductor device.

While the present invention has been particularly shown and described with reference to exemplary embodiments thereof, it will be understood by those of ordinary skill in the art that various changes in form and details may be made therein without departing from the spirit and scope of the present invention as defined by the following claims. For example, the above-described preferred embodiments can be used to eliminate the height difference between the cell region and the peripheral circuit region of a DRAM. However, embodiments of the present invention are not limited to a DRAM but can be applied to any interlayer dielectric layers having a height difference. For example, embodiments of the present invention can be applied to a merged DRAM in logic (MDL), in which DRAM cells and logic cells are simultaneously fabricated within one chip, so as to planarize an interlayer dielectric layer between a DRAM cell region where a cylinder-shaped capacitor is formed and a logic cell region where the cylinder-shaped capacitor is not formed.

1. A method of planarizing an interlayer dielectric layer, the method comprising:
forming a first interlayer dielectric layer over a first region in which a capacitor is formed and a second region adjacent to the first region, the first region being higher than the second region;
forming a second interlayer dielectric layer over the first interlayer dielectric layer, the second interlayer dielectric layer having an etching selectivity different from that of the first interlayer dielectric layer;
forming a third interlayer dielectric layer over the second interlayer dielectric layer, the third interlayer dielectric layer having an etching selectivity different from that of the second interlayer dielectric layer; and
chemical mechanical polishing the third and second interlayer dielectric layers in the first region using the third interlayer dielectric layer in the second region and the first interlayer dielectric layer in the first region as etching end points.

2. The method of claim 1, wherein the third interlayer dielectric layer has the same etching selectivity in the chemical mechanical polishing step as that of the first interlayer dielectric layer.

3. The method of claim 1, wherein the second interlayer dielectric layer has a lower etching selectivity in the chemical mechanical polishing step than that of the first and third interlayer dielectric layers.

4. The method of claim 1, wherein the third interlayer dielectric layer in the second region is higher than the first interlayer dielectric layer in the first region.

5. The method of claim 1, wherein the third and second interlayer dielectric layers are chemical mechanical polished once using a slurry having an etching selectivity between the second and third interlayer dielectric layers that is greater than 5:1.

6. The method of claim 5, wherein the first and third interlayer dielectric layers are made of a material selected from a group consisting of flow fill, SiLK, SiOC, black diamond, CORAL, undoped polysilicon, SiN, SiON, BN, anti reflection coating, and a combination of these materials, the second interlayer dielectric layer is made of a material selected from a group consisting of plasma enhanced oxide, undoped silicate glass, spin on glass, flowable oxide, boro-phosphorus silicate glass, phosphorus silicate glass, plasma enhanced tetraethylorthosilicate, and a combination of these materials, and the slurry is a ceria slurry.

7. The method of claim 1, wherein the chemical mechanical polishing of the third and second interlayer dielectric layers comprises:
removing the third interlayer dielectric layer in the first region using a first slurry that etches the third interlayer dielectric layer at a higher etch rate than that of the second interlayer dielectric layer; and
removing the second interlayer dielectric layer in the first region using a second slurry that etches the second interlayer dielectric layer at a higher etch rate than that of the first and third interlayer dielectric layers.

8. The method of claim 7, wherein the second slurry has an etching selectivity between the second and third interlayer dielectric layers that is greater than 5:1.

9. The method of claim 7, wherein the first and third interlayer dielectric layers are made of a material selected from a group consisting of flow fill, SiLK, SiOC, black diamond, CORAL, undoped polysilicon, SiN, SiON, BN, anti reflection coating, and a combination of these materials, the second interlayer dielectric layer is made of a material selected from a group consisting of plasma enhanced oxide, undoped silicate glass, spin on glass, flowable oxide, boro-phosphorus silicate glass, phosphorus silicate glass, plasma enhanced tetraethylorthosilicate, and a combination of these materials, and the second slurry is a ceria slurry.

10. The method of claim 7, wherein the first and third interlayer dielectric layers are made of a material selected from a group consisting of flow fill, SiLK, SiOC, black diamond, CORAL, undoped polysilicon, SiN, SiON, BN, anti reflection coating, and a combination of these materials, the second interlayer dielectric layer is made of a material selected from a group consisting of plasma enhanced oxide, undoped silicate glass, spin on glass, flowable oxide, boro-phosphorus silicate glass, phosphorus silicate glass, plasma enhanced tetraethylorthosilicate, and a combination of these materials, and the first slurry is a silica slurry.

11. The method of claim 1, wherein the chemical mechanical polishing of the third and second interlayer dielectric layers comprises:
removing the third and second interlayer dielectric layers in the first region using a first slurry that has the same etching selectivity between the second and third interlayer dielectric layers; and
removing the second interlayer dielectric layer in the first region using a second slurry that etches the second interlayer dielectric layer at a higher etch rate than that of the first and third interlayer dielectric layers.

12. The method of claim 11, wherein the second slurry has an etching selectivity between the second and third interlayer dielectric layers that is greater than 5:1.

13. The method of claim 11, wherein the first and third interlayer dielectric layers are made of a material selected from a group consisting of flow fill, SiLK, SiOC, black diamond, CORAL, undoped polysilicon, SiN, SiON, BN, anti reflection coating, and a combination of these materials, the second interlayer dielectric layer is made of a material selected from a group consisting of plasma enhanced oxide, undoped silicate glass, spin on glass, flowable oxide, boro-phosphorus silicate glass, phosphorus silicate glass, plasma enhanced tetraethylorthosilicate, and a combination of these materials, and the second slurry is a ceria slurry.

14. The method of claim 1, wherein the first and third interlayer dielectric layers are made of a material selected from a group consisting of SiLK, SiOC, black diamond, CORAL, undoped polysilicon, SiN, SiON, BN, anti reflection coating, and a combination of these materials, and the second interlayer dielectric layer is made of a material selected from a group consisting of plasma enhanced oxide, undoped silicate glass, spin on glass, flowable oxide, boro-phosphorus silicate glass, phosphorus silicate glass, plasma enhanced tetraethylorthosilicate, and a combination of these materials.

15. The method of claim 14, wherein the first interlayer dielectric layer is formed by first applying a material selected from the group consisting of boro-phosphorus silicate glass, phosphorus silicate glass, plasma enhanced tegraethylorthosilicate, high density plasma oxide, and a combination of these materials and then applying a material selected from the group consisting of flow fill, SiLK, SiOC, black diamond, CORAL, undoped polysilicon, SiN, SiON, BN, anti reflection coating, and a combination of these materials.

16. The method of claim 1, wherein the third interlayer dielectric layer is made of the same material as that of the first interlayer dielectric layer.

17. The method of claim 1, wherein the third and second interlayer dielectric layers are chemical mechanical polished using a slurry selected from a group consisting of a silica slurry, a ceria slurry, a mangania slurry, an alumina slurry, and a combination of these materials.

18. The method of claim 1, wherein the first and third interlayer dielectric layers are made of a material selected from a group consisting of plasma enhanced oxide, undoped silicate glass, spin on glass, flowable oxide, boro-phosphorus silicate glass, phosphorus silicate glass, plasma enhanced tetraethylorthorsilicate, and a combination of these materials, and the second interlayer dielectric layer is made of a material selected from a group consisting of flow fill, SiLK, SiOC, black diamond, CORAL, undopoed silicon, SiN, SiON, BN, anti reflection coating, and a combination of these materials.

19. A method of planarizing an interlayer dielectric layer, the method comprising:
forming a first interlayer dielectric layer both over a first region in which a capacitor is formed and a second region adjacent to the first region, the first region being higher than the second region;
forming a second interlayer dielectric layer over the first interlayer dielectric layer, the second interlayer dielectric layer having an etching selectivity different from that of the first interlayer dielectric layer; and
chemical mechanical polishing the second interlayer dielectric layer in first region using a slurry that etches the second interlayer dielectric layer at a higher etch rate than that of the first interlayer dielectric layer and using the first interlayer dielectric layer in the first region as an etching end point.

20. The method of claim 19, wherein the first interlayer dielectric layer is made of a material selected from a group consisting of plasma enhanced oxide, undoped silicate glass, flowable oxide, boro-phosphorus silicate glass, phosphorus silicate glass, plasma enhanced tetraethylorthosilicate, and a combination of these materials, and the second interlayer dielectric layer is made of a material selected from a group consisting of flow fill, SiLK, SiOC, black diamond, CORAL, undoped polysilicon, SiN, SiON, BN, anti reflection coating, and a combination of these materials.

21. The method of claim 19, wherein the second interlayer dielectric layer in the second region is higher than the first interlayer dielectric layer in the first region.

22. A method of planarizing an interlayer dielectric layer, the method comprising:
forming a first interlayer dielectric layer over a first region and a second region adjacent to the first region, the first region being higher than the second region;
forming a second interlayer dielectric layer over the first interlayer dielectric layer, the second interlayer dielectric layer having an etching selectivity different from that of the first interlayer dielectric layer;
forming a third interlayer dielectric layer over the second interlayer dielectric layer, the third interlayer dielectric layer having an etching selectivity different from that of the second interlayer dielectric layer;
chemical mechanical polishing the third interlayer dielectric layer in the first region to expose the second interlayer dielectric layer; and
chemical mechanical polishing the second interlayer dielectric layer in the first region using the third interlayer dielectric layer in the second region and the first interlayer dielectric layer in the first region as etching end points.

23. The method of claim 22, wherein the chemical mechanical polishing of the third interlayer dielectric layer comprises:
removing the third interlayer dielectric layer in the first region using a slurry that etches the third interlayer dielectric layer at a higher etch rate than that of the second interlayer dielectric layer.

24. The method of claim 22, wherein the chemical mechanical polishing of the second interlayer dielectric comprises:
removing the second interlayer dielectric layer in the first region using a slurry that etches the second interlayer dielectric layer at a higher etch rate than that of the first and third interlayer dielectric layers.

25. The method of claim 22, wherein the chemical mechanical polishing of the third and second interlayer dielectric layers comprises:
removing the third and second interlayer dielectric layers in the first region using a first slurry that has the same etching selectivity between the second and third interlayer dielectric layers; and
removing the second interlayer dielectric layer in the first region using a second slurry that etches the second interlayer dielectric layer at a higher etch rate than that of the first and third interlayer dielectric layers.
